(19) United States
(12) Patent Application Publication
(10) Pub. No.: US 2025/0218988 A1
(43) Pub. Date: Jul. 3, 2025

(54) DIRECT BOND INTERCONNECT ARCHITECTURES FOR PACKAGING ASSEMBLIES

(71) Applicant: Intel Corporation, Santa Clara, CA (US)

(72) Inventors: Yosuke KANAOKA, Chandler, AZ (US); Gang DUAN, Chandler, AZ (US); Minglu LIU, Chandler, AZ (US); Srinivas PIETAMBARAM, Chandler, AZ (US)

(21) Appl. No.: 18/398,716

(22) Filed: Dec. 28, 2023

(51) Int. Cl. H01L 23/00; H01L 23/14; H01L 23/15; H01L 23/538; H01L 25/00; H01L 25/065

(52) U.S. Cl. CPC H01L 24/08; H01L 23/145; H01L 23/15; H01L 23/5383; H01L 23/5384; H01L 23/5386; H01L 24/05; H01L 24/80; H01L 25/0655; H01L 25/50; H01L 2224/05639; H01L 2224/05644; H01L 2224/05647; H01L 2224/08225; H01L 2224/80359; H01L 2224/80895; H01L 2224/80896

(57) ABSTRACT

Assemblies and methods of manufacturing assemblies comprising semiconductor chips and package substrates wherein the semiconductor chips are operably coupled to the package substrate through a solderless direct metal-to-metal bond region. The solderless direct metal-to-metal bond region also comprises a dielectric polymer. Package substrates can comprise interconnect bridges and the semiconductor chips can be operably coupled to the interconnect bridges and can also be operably coupled to each other through the interconnect bridges.

### FIELD

Descriptions are generally related to semiconductor assemblies, and more particular descriptions are related to first level interconnects for assemblies that include semiconductor chips and semiconductor package substrates that include interconnect bridges.

### BACKGROUND

Semiconductor chips are central to intelligent devices and systems, such as personal computers, laptops, tablets, phones, servers, and other consumer and industrial products and systems. Manufacturing semiconductor chips presents a number of challenges and these challenges are amplified as devices become smaller and performance demands increase. Challenges include, for example, unwanted material interactions, precision and scaling requirements, power delivery requirements, limited failure tolerance, and material and manufacturing costs. Semiconductor chips are packaged to protect the chips and to interconnect the semiconductor chip with, for example, other semiconductor chips, devices, input/output (I/O) sources, boards, and power supplies.

High performance computing (HPC) applications, such as for example, artificial intelligence (AI) inferencing and chat generative pre-trained transformer (ChatGPT), are driving a significant package form-factor increase. Proposals for computing systems for HPC applications include integrating six times a silicon reticule size and more than 16 high bandwidth memory (HBM) units into a package. HBM can consist of stacks of dynamic random access memory (DRAM) dies. Semiconductor chip package assemblies that include multiple semiconductor chips can have interconnect bridges, such as, for example embedded multi-die interconnect bridges (EMIBs) and/or EMIBs having metallic through-bridge vias (EMIB-T) structures in the package. Interconnect bridges that are in package substrates can provide interconnections between semiconductor chips that are within a package.

### BRIEF DESCRIPTION OF THE DRAWINGS

The figures are provided to aid in understanding the invention. The figures can include diagrams and illustrations of exemplary structures, assemblies, data, methods, and systems. For ease of explanation and understanding, these structures, assemblies, data, methods, and systems, the figures are not an exhaustively detailed description. The figures therefore should not be understood to depict the entire metes and bounds of structures, assemblies, data, methods, and systems possible without departing from the scope of the invention. Additionally, features are not necessarily illustrated relatively to scale due in part to the small sizes of some features and the desire for clarity in the figures.

FIG. 1 provides an illustration of an exemplary first level interconnect architecture for semiconductor chips on a package substrate.

FIG. 2 illustrates an exemplary multi-chip package in which the package incorporates interconnect bridges.

FIG. 3 shows an additional exemplary multi-chip package in which the package incorporates interconnect bridges.

FIGS. 4A-4B illustrate a method for manufacturing a multi-chip package.

FIG. 5 shows an exemplary assembly with a multi-chip package mounted on a board.

FIG. 6 provides an exemplary computing system.

Descriptions of certain details and implementations follow, including non-limiting descriptions of the figures, which depict some examples and implementations.

### DETAILED DESCRIPTION

References to one or more examples are to be understood as describing a particular feature, structure, or characteristic included in at least one implementation of the invention. The phrases “one example” or “an example” are not necessarily all referring to the same example or embodiment. Any aspect described herein can potentially be combined with any other aspect or similar aspect described herein, regardless of whether the aspects are described with respect to the same figure or element.

The words “connected” and/or “coupled” can indicate that two or more elements are in direct physical or electrical contact with each other. The term “coupled,” however, can also mean that two or more elements are not in direct contact with each other and are instead separated by one or more elements but they may still co-operate or interact with each other, for example, physically, magnetically, or electrically.

The words “first,” “second,” and the like, do not indicate order, quantity, or importance, but rather are used to distinguish one element from another. The words “a” and “an” herein do not indicate a limitation of quantity, but rather denote the presence of at least one of the referenced items. The terms “follow” or “after” can indicate immediately following or following some other event or events. Other sequences of operations can also be performed according to alternative embodiments. Furthermore, additional operations may be added or removed depending on the application.

Disjunctive language such as the phrase “at least one of X, Y, or Z,” is used in general to indicate that an element or feature, may be either X, Y, or Z, or any combination thereof (e.g., X, Y, and/or Z). Thus, this disjunctive language should be understood not to imply that certain embodiments require at least one of X, at least one of Y, or at least one of Z to each be present.

Flow diagrams as illustrated herein provide examples of sequences of various process actions. The flow diagrams can indicate operations to be executed by a software or firmware routine, as well as physical operations. Physical operations can be performed by semiconductor processing equipment. Although shown in a particular sequence or order, unless otherwise specified, the order of the actions can be modified. Thus, the illustrated diagrams should be understood only as examples, and the process can be performed in a different order, and some actions can be performed in parallel. Additionally, one or more actions can be omitted and not all implementations will perform all actions.

Various components described can be a means for performing the operations or functions described. Each component described can include software, hardware, or a combination of these. Some components can be implemented as software modules, hardware modules, special-purpose hardware (for example, application specific hardware, application specific integrated circuits (ASICs), digital signal processors (DSPs), etc.), embedded controllers, or hardwired circuitry). Other components can be semiconductor processing and/or testing equipment that is able to perform physical operations such as, for example, lithography, material deposition (for example, chemical vapor deposition, atomic layer deposition, and/or sputtering), chemical mechanical polishing, plasma surface treatment, and etching.

To the extent various computer operations or functions are described herein, they can be described or defined as software code, instructions, configuration, and/or data. The software content can be provided via an article of manufacture with the content stored thereon, or via a method of operating a communication interface to send data via the communication interface. A machine-readable storage medium can cause a machine to perform the functions or operations described. A machine-readable storage medium includes any mechanism that stores information in a tangible form accessible by a machine (e.g., computing device), such as recordable/non-recordable media (e.g., read only memory (ROM), random access memory (RAM), magnetic disk storage media, optical storage media, flash memory devices). Instructions can be stored on the machine-readable storage medium in a non-transitory form. A communication interface includes any mechanism that interfaces to, for example, a hardwired, wireless, or optical medium to communicate to another device, such as, for example, a memory bus interface, a processor bus interface, an Internet connection, a disk controller.

Terms such as chip, die, IC (integrated circuit) chip, IC die, microelectronic chip, microelectronic die, semiconductor die, and/or semiconductor chip are interchangeable and refer to a semiconductor device comprising integrated circuits.

Semiconductor chip manufacturing processes are sometimes divided into front end of the line (FEOL) processes and back end of the line (BEOL) processes. Electronic circuits and active and passive devices within the chip, such as for example, transistors, capacitors, resistors, and/or memory cells, are manufactured in what can be referred to as FEOL processes. Memory cells include, for example, electronic circuits for random access memory (RAM), such as static RAM (sRAM), dynamic RAM (DRAM), read only memory (ROM), non-volatile memory, and/or flash memory. FEOL processes can be, for example, complementary metal-oxide semiconductor (CMOS) processes. BEOL processes include metallization of the chip where interconnects are formed in layers and the feature size of the interconnect increases in layers nearer the surface of the semiconductor chip. Interconnects in, for example, semiconductor chips that are integrated into heterogeneous packages (such as, for example, packages that include memory and logic chips), can also include through-silicon vias (TSVs) that traverse the semiconductor chip device region. Semiconductor devices that have TSVs can blur distinctions between BEOL and FEOL processes.

Semiconductor chip interconnects can be created by forming a trench or though-layer via by etching a trench or via structure into a dielectric layer and filling the trench or via with metal. Dielectric layers can comprise, for example, low-_{K} dielectrics, SiO₂, silicon nitride (SiN), silicon carbide (SiC), and/or silicon carbonitride (SiCN). Low-_{K} dielectrics include for example, fluorine-doped SiO₂, carbon-doped SiO₂, porous SiO₂, porous carbon-doped SiO₂, combinations for the foregoing, and also these materials with airgaps. Dielectric layers that include metallic features can be intermetal dielectric (ILD) features.

The terms “package,” “packaging,” “IC package,” or “chip package,” “microelectronics package,” or “semiconductor chip package” are interchangeable and generally refer to an enclosed carrier of one or more semiconductor dies, in which the semiconductor dies are attached to a package substrate and encapsulated. The package substrate provides electrical interconnects between the die(s) and other dies and/or a board, system board, main board, logic board, motherboard, or printed circuit board (PCB) for I/O (input/output) communication and power delivery. A package with multiple dies can, for example, be a system in a package.

A package substrate generally includes dielectric layers or structures having conductive structures on, through, and/or embedded in the dielectric layers. The dielectric layers can be, for example, build-up layers. Dielectric materials include Ajinomoto build-up film (ABF), although other dielectric materials are possible. Semiconductor package substrates can have cores or be coreless. Semiconductor packages having cores can have dielectric layers such as buildup layers on more than one side of a core, such as on two opposite sides of a core. Cores can include through-core vias that contain a conductive material. Other structures or devices are also possible within a package substrate.

A “core” or “package core” generally refers to a layer or substrate usually embedded within a package substrate. The core can provide structure or stiffness to a package substrate. A core is an optional feature of a package substrate. The core can be a dielectric organic or inorganic material and may have conductive vias extending through the layer. The conductive vias can include a metal, for example, copper. A package core can, for example, be comprised of a glass material (such as, for example, aluminosilicate, borosilicate, alumino-borosilicate, silica, and fused silica), silicon, silicon nitride, silicon carbide, gallium nitride, or aluminum oxide. In some examples, core materials are glass-fiber reinforced organic resins such as epoxy-based resins. A further example package substrate core is FR4 (woven glass fiber reinforces epoxy). In other examples, package substrate cores are solid amorphous glass materials.

In further examples of a package substrate core, the substrate core is a glass core comprising a solid amorphous glass material. The glass substrate core can comprise a glass such as, for example, aluminosilicate, borosilicate, alumino-borosilicate, silica, and fused silica, that additionally optionally comprises one or more of the following: Al₂O₃, B₂O₃, MgO, CaO, SrO, BaO, SnO₂, Na₂O, K₂O, SrO, P₂O₃, ZrO₂, Li₂O, Ti, and/or Zn. In further examples of glass cores, the glass can comprise silicon and oxygen, as well as optionally any one or more of: aluminum, boron, magnesium, calcium, barium, tin, sodium, potassium, strontium, phosphorus, zirconium, lithium, titanium, and/or zinc. In some examples, a glass package substrate core comprises at least 23% silicon, at least 26% oxygen by weight. In further examples, the glass package substrate core comprises at least 23% silicon, at least 26% oxygen, and at least 5% aluminum by weight.

Additionally, exemplary solid amorphous glass substrate cores can be considered to have a rectangular prism volume. The rectangular prism volume can contain vias that have been filled with one or more different materials. A material in a via can be a conducting metal such as copper. Exemplary solid amorphous glass substrate cores can have a thickness in the range of 50 μm to 1.4 mm. Additionally, the package substrate can include a multi-layer glass substrate. The package substrate in this example may be a coreless substrate. The multi-layer glass substrate can have a thickness, for example, in the range of 25 μm to 50 μm. Further, glass substrate cores can have dimensions on a side of 10 mm to 250 mm. For example, the substrate core could be 10 mm by 10 mm up to 250 mm by 250 mm in two dimensions, but substrate cores do not necessarily have to have the same value in both dimensions.

A package substrate can include one or more interconnect bridges. An interconnect bridge can be partially, fully, or not embedded into the package substrate. An interconnect bridge provides interconnects between chips that are housed on the package substrate. The interconnects can be for I/O between the chips. Some interconnect bridges, such as ones that have conducting through-bridge vias, can also provide power to an operably connected chip. The interconnect bridge can include regions having traces that have a smaller width dimension (the smallest dimension of the trace), a smaller height dimension, and/or a length dimension than the vias and traces of the surrounding package substrate. For example, width dimensions (or smallest dimension) can be 3 μm or less and/or 10 μm or less in some regions. The interconnect bridges can also have smaller trace spacings than the surrounding package substrate. For example, trace center-to-center spacings can be 3 μm and/or less or 10 μm or less in some regions. The bridge can comprise, for example, a silicon substrate, a silicon-on-insulator substrate, a float glass substrate, a borosilicate glass substrate, a silicon dioxide substrate, and/or a silicon nitride substrate. The substrate can comprise, for example, one or more dielectric layers that are comprise of, silicon oxides, silicon nitride, silicon oxynitride, carbon-doped oxide, methyl silsesquioxane, hydrogen silsesquioxane, die backside film (DBF), an epoxy film, a B-stage epoxy film, other dielectric material. The bridge can also be a coreless substrate comprised of a plurality of dielectric layers. The dielectric layers can be, for example, die backside film (DBF), an epoxy film, a B-stage epoxy film, other dielectric material. Other materials are possible.

For packages that include interconnect bridges, the pitch in the interconnect bridge region for first level interconnects (FLIs) assemblies can be less than the pitch for other regions of the FLI assembly. The pitch in the interconnect bridge region can be, for example, less than or equal to 25 μm. A low regression bump thickness variation (rBTV) can be more difficult to obtain in mixed pitch systems where there are pitches are less than or equal to 25 μm. A larger rBTV can negatively impact package assembly yields.

Thermal compression bonding (TCB) can employ solder on a die or solder on both the die and the package substrate to form solder joint FLIs. The chip gap height (CGH) control across the die to substrate plane is critical and can be compensated for by pre-measurement of rBTV and bond head tilt to achieve a quality controlled collapse chip connection (C4) bonding. After formation of solder joint FLIs, an epoxy underfill is dispensed to encapsulate the C4 interface to enhance reliability.

For packages where bump pitches are less than or equal to 25 μm, CGH control can be more difficult. Tighter bump pitches mean that the pad sizes to apply solder will be smaller also. Forming healthy FLIs using TCB can be more difficult at smaller pitches and assembly yields can suffer. Yield impacts are magnified as packages integrate larger numbers of chips.

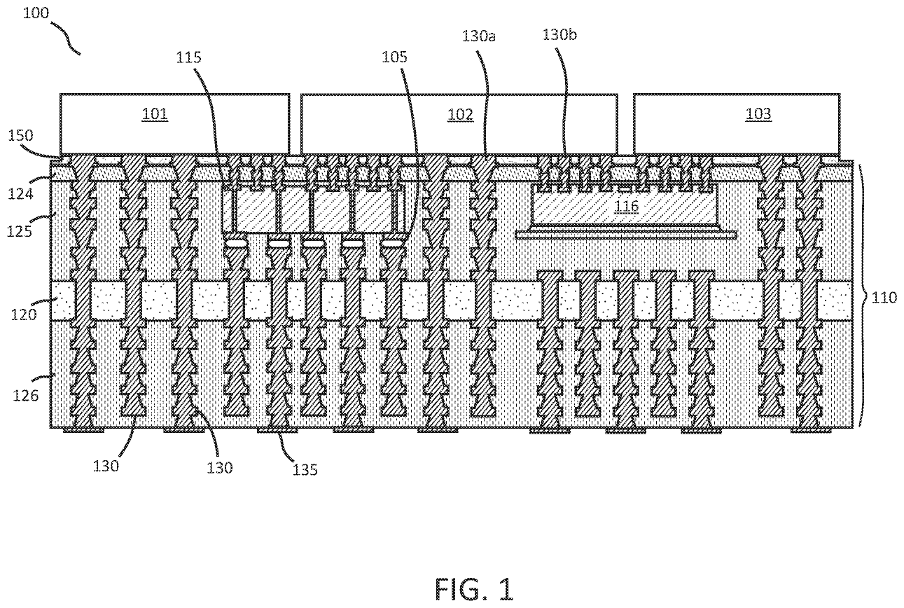

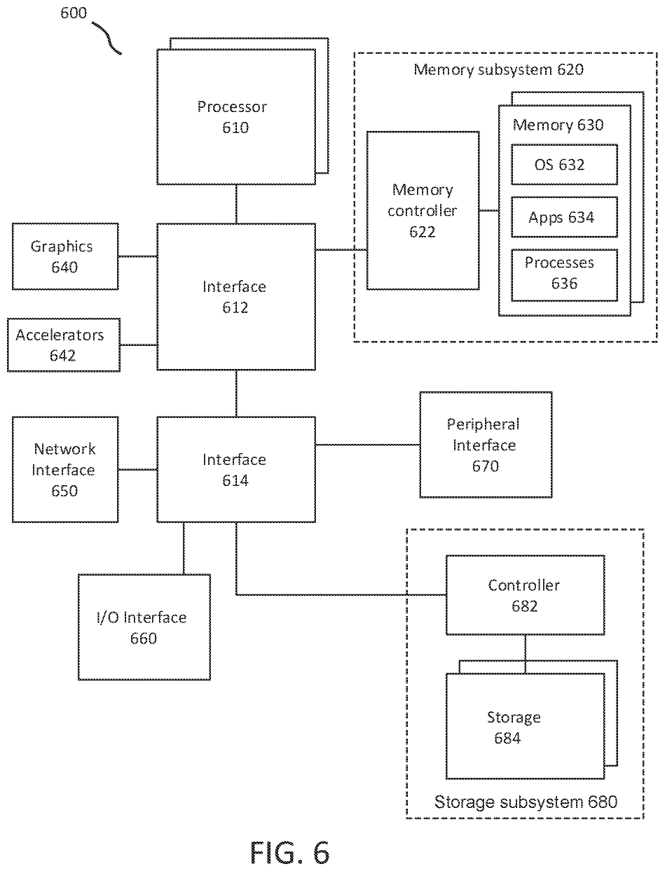

FIG. 1 illustrates a semiconductor chip package assembly 100. The package assembly 100 includes semiconductor chips 101, 102, and 103. The semiconductor chips 101, 102, and 103 can be, for example, any combination of microprocessors, CPUs (central processing units), GPUs (graphics processing units), processing cores, system on a chips, other processing hardware, a combination of processors or processing cores, programmable general-purpose or special-purpose microprocessors, accelerators, DSPs, I/O management, programmable controllers, ASICs, programmable logic devices (PLDs), high bandwidth memory (HBM), and/or other memory devices. The semiconductor chips 101, 102, and 103 can be any of the chips, for example, described herein with respect to FIG. 6. The package assembly also includes package substrate 110. Package substrate 110 includes interconnect bridges 115 and 116. Interconnect bridges 115 and 116 can be partially or fully embedded in the package substrate 110. The interconnect bridges 115 and 116 can be embedded multi-die interconnect bridges (EMIBs). The interconnect bridges 115 and 116 contain vias and traces that allow the connected semiconductor chips 101 and 102 or 102 and 103, respectively, to communicate with each other. The interconnect bridge 115 includes through-bridge vias (TBVs) and can be for example, an EMIB-T. In this example, the package substrate 120 includes one embedded interconnect bridge 115 that has TBVs and one embedded interconnect bridge 116 that does not have TBVs, however other combinations and numbers of interconnect bridges that have TBVs and that do not have TBVs are possible, such as for example, packages that have only interconnect bridges that do not have TBVs and interconnect bridges that all have TBVs. Interconnect bridges typically have tighter connection pitches than other areas of a package substrate that also make interconnections with semiconductor dies.

The package substrate 110 also includes a substrate core 120 which can be an organic substrate core or glass substrate core as described herein. Although this package substrate 110 includes a substrate core 120, coreless substrates are also possible. Additionally, the package substrate 110 has a dielectric regions 124, 125 and 126 which can be one or more layers of dielectric (such as build-up layers) having metallic traces and vias 130 and board-side pads 135. Board-side pads 135 can connect to a board (e.g., a motherboard, a printed circuit board, a system board, a main board, or a logic board). A package with multiple dies can, for example, be a system in a package). Connection to a board can be through solder joints. The metallic traces and vias 130 can be, for example, comprised of copper. The interconnect bridge 115 is connected to traces and vias 130 through metallic interconnections 105 which can be, for example, comprised of solder.

The semiconductor chips 101, 102, and 103 are joined to the package substrate 110 and there is a polymer region 150 is in the first level interconnect region between the semiconductor chips 101, 102, and 103 and the package substrate 110. The FLIs solderless interconnects 130a and 130b where the package substrate 110 has been joined to the semiconductor chips 101, 102, and 103 can be comprised of, for example, copper/copper, gold/gold, silver/silver or other conducting material that is amenable to forming solderless metal-to-metal interconnections (where the region joined on the semiconductor chip 101, 102, or 103 is comprised of copper (gold, silver, or other material) and the region joined on the package substrate 110 is comprised of copper (gold, silver, or other material). Combinations of the foregoing materials are also possible. Direct bond interconnections 130a and 130b can be solderless metal-to-metal connections. Pitches between solderless interconnects 130a and 130b can be 25 μm or less. Polymer dielectric region 150 can comprise a material such as for example, ABF, polyimides, benzocyclobutene (1,2-dihydrobenzocyclobutene) polymers (BCBs), cyclic-olefin polymers (COP), and/or another material that is amenable to forming an adhesion bond during a chip attach process. Generally, materials that are useful for polymer dielectric region 150 have a bonding temperature and thermal resistance for curing that is up to 400° C., the material is compatible with chemical mechanical polishing (CMP) processes, and the material has a low coefficient of thermal expansion (CTE) that is comparable to other materials that are part of a package substrate assembly. For example, silicon has a CTE of 2.6 ppm/° C., Ajinomoto build-up film (ABF) has a CTE of about 39 ppm/° C., and Cu has a CTE of 17 ppm/° C. Useful materials for polymer dielectric region 150 can also exhibit a dielectric constant that is between 2 and 5 (at 1 kHz).

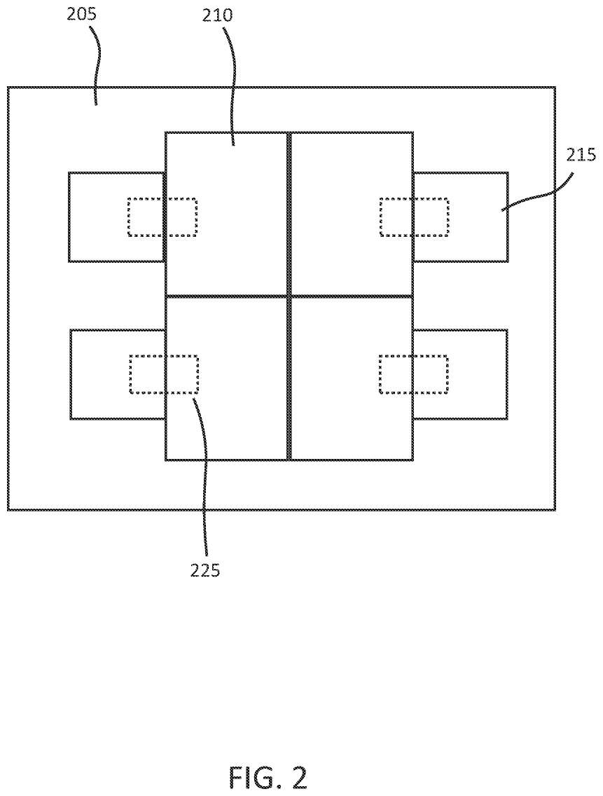

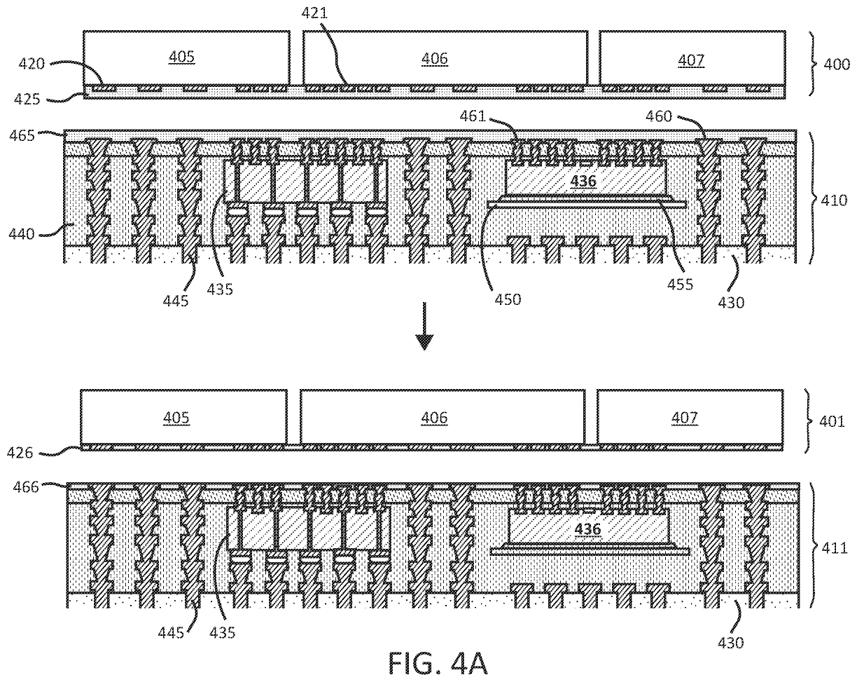

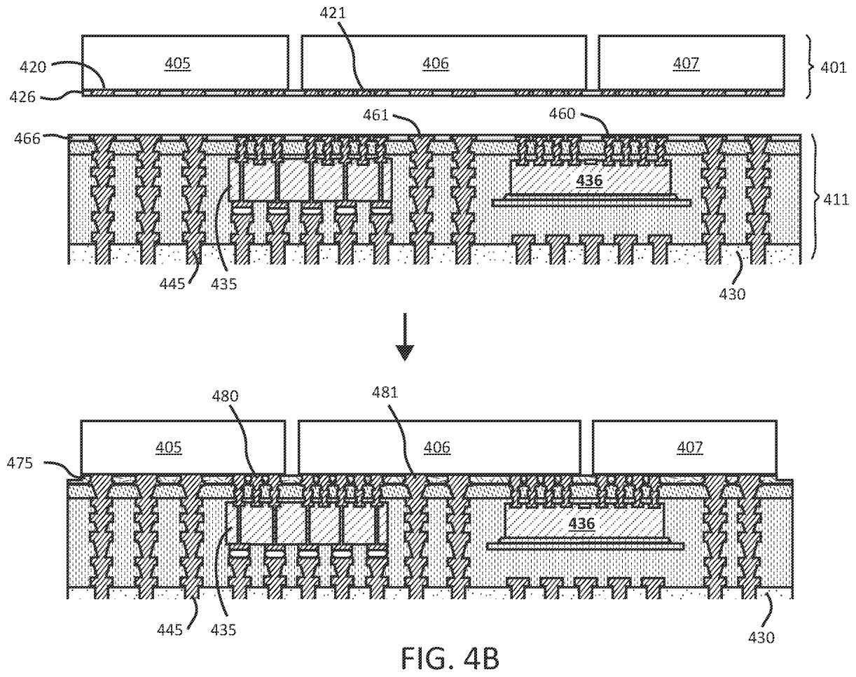

FIG. 2 shows an example configuration for packaged semiconductor chips mounted on a board. Other configurations are possible. FIG. 2 can be considered a top-down view in relation to FIG. 1 which can be considered a cross-section view of packaged semiconductor chips. In FIG. 2, a board 205 (e.g., a motherboard, a PCB, a system board, a logic board, a circuit board, or a main board) has packaged semiconductor chips 210 and 215 operably coupled to the board 205. Interconnect bridges 225 are shown with a dashed line and are covered by packaged semiconductor chips 210 and 215 in this view. The semiconductor chip attachment to a package substrate FLI region can include a polymer region as described herein with respect to FIG. 1 (e.g., polymer region 150) and FIGS. 4A-4B and FLIs can be solderless direct bond interconnections as described herein with respect to FIG. 1 (e.g., solderless metal-to-metal interconnects 130a and 130b). The interconnect bridges 225 can be more than one interconnect bridge, can be interconnect bridges that are with or without TBVs, and semiconductor chip package substrates can contain more than one type of interconnect bridge. For example, one or more chips 210 can be a processor or a field programmable gate array (FPGA), and one or more of the chips 215 can be a HBM die stack and/or one or more of the chips 215 can transceiver die.

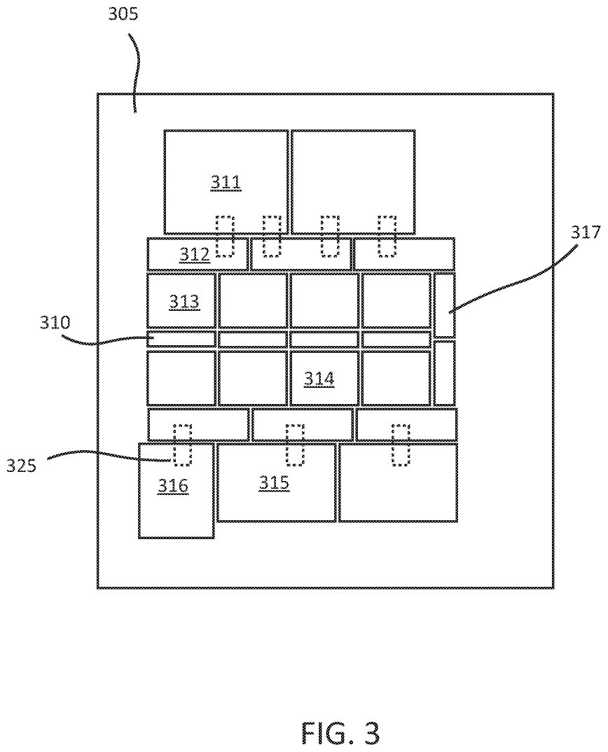

FIG. 3 shows an exemplary configuration for packaged semiconductor chips mounted on a circuit board. FIG. 3 can be considered a top-down view in relation to FIG. 1 which can be considered a cross-section view of packaged semiconductor chips. In FIG. 3, a board 305 (e.g., a motherboard, a printed circuit board, a system board, a main board, a logic board, or a circuit board) has packaged semiconductor chips 310, 311, 312, 313, 314, 315, 316, and 317 operably coupled to the board 305. Interconnect bridges 325 are shown with a dashed line and are covered by packaged semiconductor chips 310 and 315 in this view. The semiconductor chip attachment to a package substrate FLI region can include a polymer region as described herein with respect to FIG. 1 (e.g., polymer region 150) and FIGS. 4A-4B and FLIs can be solderless direct bond interconnections as described herein with respect to FIG. 1 (e.g., solderless metal-to-metal interconnects 130a and 130b). The interconnect bridges 325 can be more than one interconnect bridge, can be interconnect bridges that are with or without TBVs, and semiconductor chip package substrates can contain more than one type of interconnect bridge. One or more of semiconductor chips 312, 313, and 314 can be packaged using an active interposer that allows one or more of semiconductor chips 312, 313, and 314 to communicate with each other.

Additionally, in FIGS. 2 and 3, the semiconductor chips can be any combination of microprocessors, CPUs (central processing units), GPUs (graphics processing units), processing cores, system on a chips, other processing hardware, a combination of processors or processing cores, programmable general-purpose or special-purpose microprocessors, accelerators, DSPs, I/O management, programmable controllers, ASICs, programmable logic devices (PLDs), high bandwidth memory (HBM), and/or other memory devices. The semiconductor chip packages can be heterogeneous packages that incorporate different types of chips into one package. The semiconductor chips can be any of the chips, for example, described herein with respect to FIG. 6. The semiconductor chip interconnect bridges 225 and 325 can be any combination of interconnect bridges 115 and 116, for example, as described with respect to FIG. 1. The interconnect bridges described herein generally can be used between semiconductor chips in various package configurations and the foregoing examples are not meant to limit of the types of assemblies that are possible.

FIGS. 4A-4B describe a method for interconnecting semiconductor chips with a package substrate. In FIGS. 4A-4B, semiconductor chips 405, 406, and 407 have direct bonding interconnect regions 420 and 421. Direct bonding interconnect regions 420 and 421 can be pad, pin, bump, or pillar shaped, or another type of protrusion, and can be comprised of copper, gold, silver, other conducting material that can be used to form a direct connection bond, or a combination thereof. The direct connection bond can be made without solder. In semiconductor chip assembly 400, semiconductor chips 405, 406, and 407 also have a polymer dielectric layer 425. Polymer dielectric layer 425 can comprise a material such as for example, ABF, polyimides, benzocyclobutene (1,2-dihydrobenzocyclobutene) polymers (BCBs), cyclic-olefin polymers (COP), and/or another material that is amenable to forming an adhesion bond during a chip attach process. The material can be a material as described herein with respect, for example, to FIG. 1.

Package substrate 410 is shown in part for ease of illustration. Package substrate 410 includes interconnect bridges 435 and 436. The interconnect bridges 435 and 436 can be, for example, embedded multi-die interconnect bridges (EMIBs). The interconnect bridge 435 includes through-bridge vias (TBVs) and can be for example, an EMIB-T. Other combinations and numbers of interconnect bridges that have TBVs and that do not have TBVs are possible, such as for example, packages that have only interconnect bridges that do not have TBVs and bridges that all have TBVs. The interconnect bridges 435 and 436 can be partially embedded or fully embedded in package substrate 410. The package substrate 410 also includes a core 430 which can be an organic core substrate or glass core substrate as described herein. Additionally, the package substrate 410 has a dielectric region 440 which can be layers of dielectric (such as build-up layers) having metallic traces and vias 445. The package substrate 410 can also include an etch stop region 450 and dielectric adhesive region 455 associated with an interconnect bridge 435. The etch stop region 450 can be a copper plane and the dielectric adhesive region 455 can comprise an epoxy.

Package substrate 410 also includes direct bonding interconnect regions 460 and 461 that can be pad or pillar shaped, or be another type of protrusion, and can be comprised of copper, gold, silver, other conducting material that can be used to form a direct connection bond, or a combination thereof. The shape of the protrusion is one that will enable direct bonding interconnection after a polymer application and surface removal process. Direct bonding interconnect regions 461 associated with EMIB can have a smaller pitch than direct bonding interconnect regions 460 in other areas of the package. A polymer dielectric layer 465 is on a surface of the package substrate 410. Polymer dielectric layer 465 can comprise a material such as for example, ABF, polyimides, benzocyclobutene (1,2-dihydrobenzocyclobutene) polymers (BCBs), cyclic-olefin polymers (COP), and/or another material that is amenable to forming an adhesion bond during a chip attach process. The material can be a material as described herein with respect, for example, to FIG. 1.

The polymer dielectric layers 425 and 465 are partially removed from the surface of the semiconductor chip assembly 400 and the package substrate 410, respectively, partially exposing direct bonding interconnect regions 420 and 421 and 460 and 461, and forming semiconductor chip assembly 401 and package substrate 411, respectively. The polymer dielectric layers 425 and 465 can be partially removed, through, for example, a grinding and/or a chemical mechanical polishing (CMP) process. The modified polymer dielectric layers 425 and 465 are shown as dielectric layers 426 and 466, respectively.

In FIG. 4B, semiconductor chip assembly 401 and package substrate 411 are attached to each other. The attachment process creates a direct metal-to-metal bond between the exposed direct bonding interconnect regions 420 and 421 of the semiconductor chip assembly 401 and the direct bonding interconnect regions 460 and 461 of the package substrate 411. A plasma process, a hydration process, or other surface activation process can be applied to the surfaces that will be bonded together to activate the surfaces of the semiconductor chip assembly 400 and the package substrate 410 for bonding. The attachment process can be done, for example, through annealing and applying pressure to fuse the direct bonding metal-to-metal interconnect regions 420 and 421 and 460 and 461 and the polymer regions 426 and 466. The attachment process can be a thermal compression bonding process. The bonding process creates direct bond interconnect regions 480 and 481 and polymer region 475. The attachment and interconnection process of FIGS. 4A-4B can be done without using solder and can be considered a direct bonding process. The method of FIGS. 4A-4B can be used with various technologies, such as, for example, packages having organic substrates, glass core and/or carrier based substrates, and with various form factors such as wafer-level or panel-level assembly processes that either have or do not have fan-out redistribution layers.

The semiconductor chips 405, 406, and 407 can be, for example, any combination of microprocessors, CPUs (central processing units), GPUs (graphics processing units), processing cores, system on a chips, other processing hardware, a combination of processors or processing cores, programmable general-purpose or special-purpose microprocessors, accelerators, DSPs, 1/O management, programmable controllers, ASICs, programmable logic devices (PLDs), high bandwidth memory (HBM), and/or other memory devices. The semiconductor chips 405, 406, and 407 can be any of the chips, for example, described herein with respect to FIG. 6.

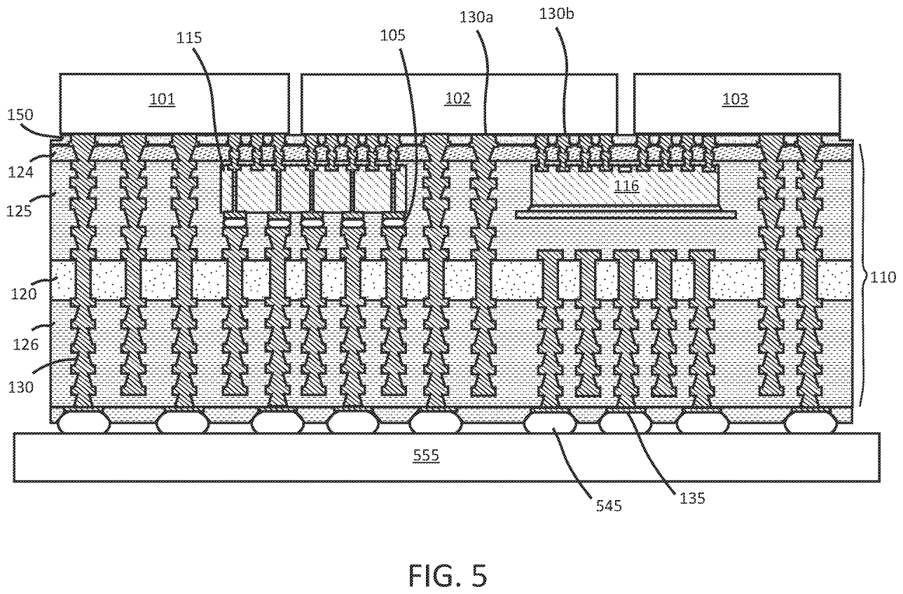

FIG. 5 illustrates an assembly, such as that of FIG. 1 that is coupled to a circuit board. Where the numbering of parts is the same for FIGS. 1 and 5, the descriptions herein with respect to FIG. 1 can be used for FIG. 5. In FIG. 5, the package substrate 110 has been coupled to a circuit board 555 through the board-side pads 135 with solder regions 545. The circuit board 555 can be, for example, a motherboard, a printed circuit board, a system board, a logic board, or mainboard. The circuit board 555 can include a power supply that can control the amount of current and/or voltage going to components of the circuit board 555, such as the amount of current and/or voltage supplied to the semiconductor chips 405, 406, and 407. Power can be supplied to packaged chips through-bridges that have TBVs. The circuit board 555 can also provide interconnections processors and other computing devices and memory, such as DRAM.

FIG. 6 depicts an example computing system. The computing system can be a system used, for example for running equipment in a semiconductor fabrication plant. For example, instructions for operating processing equipment to perform one or more aspects of the process described in FIGS. 4A-4B can be stored and/or run on the computing system. The computing system employed can include more, different, or fewer features than the one described with respect to FIG. 6.

Computing system 600 includes processor 610, which provides processing, operation management, and execution of instructions for system 600. Processor 610 can include any type of microprocessor, CPU (central processing unit), GPU (graphics processing unit), processing core, or other processing hardware to provide processing for system 600, or a combination of processors or processing cores. Processor 610 controls the overall operation of system 600, and can be or include, one or more programmable general-purpose or special-purpose microprocessors, DSPs, programmable controllers, ASICs, programmable logic devices (PLDs), or the like, or a combination of such devices.

In one example, system 600 includes interface 612 coupled to processor 610, which can represent a higher speed interface or a high throughput interface for system components needing higher bandwidth connections, such as memory subsystem 620 or graphics interface components 640, and/or accelerators 642. Interface 612 represents an interface circuit, which can be a standalone component or integrated onto a processor die. Where present, graphics interface 640 interfaces to graphics components for providing a visual display to a user of system 600. In one example, the display can include a touchscreen display.

Accelerators 642 can be a fixed function or programmable offload engine that can be accessed or used by a processor 610. For example, an accelerator among accelerators 642 can provide data compression (DC) capability, cryptography services such as public key encryption (PKE), cipher, hash/authentication capabilities, decryption, or other capabilities or services. In some cases, accelerators 642 can be integrated into a CPU socket (e.g., a connector to a motherboard (or a circuit board, a printed circuit board, a mainboard, a system board, or a logic board) that includes a CPU and provides an electrical interface with the CPU). For example, accelerators 642 can include a single or multi-core processor, graphics processing unit, logical execution unit single or multi-level cache, functional units usable to independently execute programs or threads, application specific integrated circuits (ASICs), neural network processors (NNPs), programmable control logic, and programmable processing elements such as field programmable gate arrays (FPGAs) or programmable logic devices (PLDs). Accelerators 642 can provide multiple neural networks, CPUs, processor cores, general purpose graphics processing units, or graphics processing units can be made available for use by artificial intelligence (AI) or machine learning (ML) models.

Memory subsystem 620 represents the main memory of system 600 and provides storage for code to be executed by processor 610, or data values to be used in executing a routine. Memory subsystem 620 can include one or more memory devices 630 such as read-only memory (ROM), flash memory, one or more varieties of random access memory (RAM) such as static RAM (SRAM), dynamic RAM (DRAM), synchronous DRAM (SDRAM) and/or or other memory devices, or a combination of such devices. Memory 630 stores and hosts, among other things, operating system (OS) 632 that provides a software platform for execution of instructions in system 600, and stores and hosts applications 634 and processes 636. In one example, memory subsystem 620 includes memory controller 622, which is a memory controller to generate and issue commands to memory 630. The memory controller 622 could be a physical part of processor 610 or a physical part of interface 612. For example, memory controller 622 can be an integrated memory controller, integrated onto a circuit within processor 610.

System 600 can also optionally include one or more buses or bus systems between devices, such memory buses, graphics buses, and/or interface buses. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a peripheral component interface (PCI) or PCI express (PCIe) bus, a Hyper Transport or industry standard architecture (ISA) bus, a small computer system interface (SCSI) bus, a universal serial bus (USB), or a Firewire bus.

In one example, system 600 includes interface 614, which can be coupled to interface 612. In one example, interface 614 represents an interface circuit, which can include standalone components and integrated circuitry. In one example, user interface components or peripheral components, or both, couple to interface 614. Network interface 650 provides system 600 the ability to communicate with remote devices (e.g., servers or other computing devices) over one or more networks. Network interface 650 can include an Ethernet adapter, wireless interconnection components, cellular network interconnection components, USB, or other wired or wireless standards-based or proprietary interfaces. Network interface 650 can transmit data to a device that is in the same data center or rack or a remote device, which can include sending data stored in memory.

Some examples of network interface 650 are part of an infrastructure processing unit (IPU) or data processing unit (DPU), or used by an IPU or DPU. An xPU can refer at least to an IPU, DPU, GPU, GPGPU (general purpose computing on graphics processing units), or other processing units (e.g., accelerator devices). An IPU or DPU can include a network interface with one or more programmable pipelines or fixed function processors to perform offload of operations that could have been performed by a CPU. The IPU or DPU can include one or more memory devices.

In one example, system 600 includes one or more input/output (I/O) interface(s) 660. I/O interface 660 can include one or more interface components through which a user interacts with system 600 (e.g., audio, alphanumeric, tactile/touch, or other interfacing). Peripheral interface 670 can include additional types of hardware interfaces, such as, for example, interfaces to semiconductor fabrication equipment and/or electrostatic charge management devices.

In one example, system 600 includes storage subsystem 680. Storage subsystem 680 includes storage device(s) 684, which can be or include any conventional medium for storing data in a nonvolatile manner, such as one or more magnetic, solid state, and/or optical based disks. Storage 684 can be generically considered to be a “memory,” although memory 630 is typically the executing or operating memory to provide instructions to processor 610. Whereas storage 684 is nonvolatile, memory 630 can include volatile memory (e.g., the value or state of the data is indeterminate if power is interrupted to system 600). In one example, storage subsystem 680 includes controller 682 to interface with storage 684. In one example controller 682 is a physical part of interface 612 or processor 610 or can include circuits or logic in both processor 610 and interface 614.

A power source (not depicted) provides power to the components of system 600. More specifically, power source typically interfaces to one or multiple power supplies in system 600 to provide power to the components of system 600.

Exemplary systems may be implemented in various types of computing, smart phones, tablets, personal computers, and networking equipment, such as switches, routers, racks, and blade servers such as those employed in a data center and/or server farm environment.

### EXAMPLES

A semiconductor chip assembly comprises: at least two semiconductor chips; a package substrate wherein the package substrate comprises at least one embedded interconnect bridge; and a region between the at least two semiconductor chips and the package substrate wherein the region comprises a dielectric polymer, wherein the region comprises solderless metal-to-metal interconnects, wherein the solderless metal-to-metal interconnects operably connect the at least two semiconductor chips to the package substrate, and wherein solderless metal-to-metal interconnects operably connect the at least two semiconductor chips to the at least one embedded interconnect bridge in the package substrate. The at least one embedded interconnect bridge can include through-bridge vias. The solderless metal-to-metal interconnects can comprise copper, gold, silver, or a combination thereof. The dielectric polymer can comprise a polyimide, a benzocyclobutene polymer, or a cyclic-olefin polymer. The package substrate can have a substrate core that is comprised of an organic material. The package substrate can have a substrate core that is comprised of a solid amorphous glass material. A pitch between the solderless metal-to-metal interconnects can be less than 25 μm.

A computing system can comprise: a processor; a package substrate wherein the package substrate comprises at least one interconnect bridge; a region between the processor and the package substrate wherein the region comprises a dielectric polymer, wherein the region comprises solderless metal-to-metal interconnects, wherein the solderless metal-to-metal interconnects operably connect the processor to the package substrate, and wherein solderless metal-to-metal interconnects operably connect the processor to the at least one interconnect bridge in the package substrate; and a circuit board wherein the package substrate is operably connected to the circuit board, wherein and the circuit board comprises a power supply, and wherein the power supply is capable providing power to the package substrate. The computing system can also include a high bandwidth memory device wherein the high bandwidth memory device is operably connected to the package substrate through solderless metal-to-metal interconnects. The circuit board can operably connect the processor to dynamic random access memory. The at least one interconnect bridge can include through-bridge vias that are capable of supplying power from the circuit board to the processor. The solderless metal-to-metal interconnects can comprise copper, gold, silver, or a combination thereof. The dielectric polymer can comprise a polyimide, a benzocyclobutene polymer, or a cyclic-olefin polymer. A pitch between the solderless metal-to-metal interconnects can be less than 25 μm.

A method for forming a semiconductor chip package assembly comprises: partially removing a dielectric polymer from a surface of two or more semiconductor chips wherein partially removing a dielectric polymer partially exposes direct bonding interconnect regions on a surface of the one or more semiconductor chips; partially removing dielectric polymer from a surface of a package substrate wherein partially removing dielectric polymer from a surface of the package substrate partially exposes direct bonding interconnect regions on a surface of the package substrate and wherein the package substrate comprises an interconnect bridge; and joining the direct bonding interconnect regions on a surface of the one or more semiconductor chips with direct bonding interconnect regions on a surface of the package substrate, wherein joining forms operable interconnections between the two or more semiconductor chips and the package substrate, and wherein dielectric polymer is between the operable interconnections. The direct bonding interconnect regions can include a plurality of pillars or a plurality of pads. The method can also include exposing the surface of the package substrate to a plasma process. The package substrate can comprise an embedded interconnect bridge that includes through-bridge vias. The direct bonding interconnect regions on a surface of the one or more semiconductor chips can comprise copper, gold, silver, or a combination thereof. The dielectric polymer can comprise a polyimide, a benzocyclobutene polymer, or a cyclic-olefin polymer.

Besides what is described herein, various modifications can be made to what is disclosed and implementations of the invention without departing from their scope. Therefore, the illustrations and examples herein should be construed in an illustrative, and not a restrictive sense. The scope of the invention should be measured solely by reference to the claims that follow.

What is claimed is:

1. A semiconductor chip assembly comprising:
at least two semiconductor chips;
a package substrate wherein the package substrate comprises at least one embedded interconnect bridge; and
a region between the at least two semiconductor chips and the package substrate wherein the region comprises a dielectric polymer, wherein the region comprises solderless metal-to-metal interconnects, wherein the solderless metal-to-metal interconnects operably connect the at least two semiconductor chips to the package substrate, and wherein solderless metal-to-metal interconnects operably connect the at least two semiconductor chips to the at least one embedded interconnect bridge in the package substrate.

2. The semiconductor chip assembly of claim 1 wherein the at least one embedded interconnect bridge includes through-bridge vias.

3. The semiconductor chip assembly of claim 1 wherein the solderless metal-to-metal interconnects comprise copper, gold, silver, or a combination thereof.

4. The semiconductor chip assembly of claim 1 wherein the dielectric polymer comprises a polyimide, a benzocyclobutene polymer, or a cyclic-olefin polymer.

5. The semiconductor chip assembly of claim 1 wherein the package substrate has a substrate core and the substrate core is comprised of an organic material.

6. The semiconductor chip assembly of claim 1 wherein the package substrate has a substrate core and the substrate core is comprised of a solid amorphous glass material.

7. The semiconductor chip assembly of claim 1 wherein a pitch between the solderless metal-to-metal interconnects is less than 25 μm.

8. A computing system comprising:
a processor;
a package substrate wherein the package substrate comprises at least one interconnect bridge;
a region between the processor and the package substrate wherein the region comprises a dielectric polymer, wherein the region comprises solderless metal-to-metal interconnects, wherein the solderless metal-to-metal interconnects operably connect the processor to the package substrate, and wherein solderless metal-to-metal interconnects operably connect the processor to the at least one interconnect bridge in the package substrate; and
a circuit board wherein the package substrate is operably connected to the circuit board, wherein and the circuit board comprises a power supply, and wherein the power supply is capable providing power to the package substrate.

9. The computing system of claim 8 also including a high bandwidth memory device wherein the high bandwidth memory device is operably connected to the package substrate through solderless metal-to-metal interconnects.

10. The computing system of claim 8 wherein the circuit board operably connects the processor to dynamic random access memory.

11. The computing system of claim 8 wherein the at least one interconnect bridge includes through-bridge vias that are capable of supplying power from the circuit board to the processor.

12. The computing system of claim 8 wherein the solderless metal-to-metal interconnects comprise copper, gold, silver, or a combination thereof.

13. The computing system of claim 8 wherein the dielectric polymer comprises a polyimide, a benzocyclobutene polymer, or a cyclic-olefin polymer.

14. The computing system of claim 8 wherein a pitch between the solderless metal-to-metal interconnects is less than 25 μm.

15. A method for forming a semiconductor chip package assembly comprising:
partially removing a dielectric polymer from a surface of two or more semiconductor chips wherein partially removing a dielectric polymer partially exposes direct bonding interconnect regions on a surface of the one or more semiconductor chips;
partially removing dielectric polymer from a surface of a package substrate wherein partially removing dielectric polymer from a surface of the package substrate partially exposes direct bonding interconnect regions on a surface of the package substrate and wherein the package substrate comprises an interconnect bridge; and
joining the direct bonding interconnect regions on a surface of the one or more semiconductor chips with direct bonding interconnect regions on a surface of the package substrate, wherein joining forms operable interconnections between the two or more semiconductor chips and the package substrate, and wherein dielectric polymer is between the operable interconnections.

16. The method of claim 15 wherein direct bonding interconnect regions include a plurality of pillars or a plurality of pads.

17. The method of claim 15 also including exposing the surface of the package substrate to a plasma process.

18. The method of claim 15 wherein the package substrate comprises an embedded interconnect bridge that includes through-bridge vias.

19. The method of claim 15 wherein direct bonding interconnect regions on a surface of the one or more semiconductor chips comprise copper, gold, silver, or a combination thereof.

20. The method of claim 15 wherein the dielectric polymer comprises a polyimide, a benzocyclobutene polymer, or a cyclic-olefin polymer.
